(19) United States
(12) Patent Application Publication
(10) Pub. No.: US 2026/0165007 A1
(43) Pub. Date: Jun. 11, 2026

(54) DISPLAY PANEL AND DISPLAY DEVICE INCLUDING THE SAME

(71) Applicant: LG DISPLAY CO., LTD., Seoul (KR)

(72) Inventors: Yong Cheol KIM, Paju-si (KR); Kyu Il HAN, Paju-si (KR); Hyun Sook JEON, Paju-si (KR)

(73) Assignee: LG DISPLAY CO., LTD., Seoul (KR)

(21) Appl. No.: 19/303,448

(22) Filed: Aug. 19, 2025

(30) Foreign Application Priority Data
Dec. 10, 2024 (KR) 10-2024-0182201

(51) Int. Cl. H10K 59/80; H10K 59/122; H10K 59/40; H10K 59/65

(52) U.S. Cl. CPC H10K 59/879; H10K 59/122; H10K 59/40; H10K 59/65

(57) ABSTRACT

A display panel and a display device including the same are discussed. The display device can include a display panel having a display area and an optical area, and a sensor arranged to correspond to the optical area. The display panel can include a substrate, a circuit layer arranged on the substrate, an anode electrode arranged on the circuit layer, an organic compound layer arranged on the anode electrode and including a light-emitting area, a cathode electrode and a pattern layer arranged on the organic compound layer, an encapsulation layer arranged on the cathode electrode and the pattern layer, a touch sensor layer arranged on the encapsulation layer, and a plurality of lenses configured to overlap the pattern layer.

### CROSS-REFERENCE TO RELATED APPLICATION

This application claims priority to Korean Patent Application No. 10-2024-0182201, filed in the Republic of Korea on Dec. 10, 2024, the disclosure of which is hereby expressly incorporated by reference in its entirety into the present application.

### BACKGROUND

### Technical Field

Embodiments relate to a display panel and a display device including the same.

### Discussion of the Related Art

Electroluminescence display devices can be classified into inorganic light-emitting display devices and organic light-emitting displays according to a material of an emission layer. An active matrix organic light-emitting display device includes an organic light-emitting diode (OLED) that generates light by itself and has advantages in terms of a high response rate, high luminous efficiency, high luminance, and a large viewing angle. In an organic light-emitting display device, an OLED is formed at each pixel. The organic light-emitting display device has a high response rate, high luminous efficiency, high luminance, and a large viewing angle and is capable of expressing black gradation in perfect or near perfect black, thereby achieving a high contrast ratio and a high color reproduction rate.

Multi-media functions of mobile terminals are being improved. For example, a camera is basically built into a smart phone, and the resolution of the camera is increasing to the level of a conventional digital camera. However, the front camera of the smart phone limits the screen design, which can make it difficult to design the screen. In order to reduce the space occupied by the camera, a screen design including a notch or punch hole has been adopted for smart phones, but the screen size can still be limited due to the notch or punch hole, thereby making it difficult to implement a full-screen display.

To implement a full-screen display, a method has been proposed in which an optical area where low-resolution pixels are arranged is provide within a screen of a display panel, and electronic components such as a camera and various sensors are arranged below the display panel, at a position opposite to the optical area. Here, each of the pixels can include a plurality of sub-pixels.

However, lateral leakage current flowing between adjacent light-emitting elements can occur. In addition, light generated by lateral leakage current in the optical area can affect the camera and various sensors. For example, for the camera, the light can cause color distortion in an image. In addition, for an infrared sensor, the light can cause an error in identifying a target object (such as a face).

Therefore, there is a demand for a structurally improved display device configured to prevent the generation of light which can be caused by lateral leakage current.

### SUMMARY OF THE DISCLOSURE

Embodiments of the present disclosure provide a display panel, which prevents or reduces the generation of light caused by lateral leakage current, and a display device including the same.

Objectives to be solved by embodiments of the present disclosure are not limited to the objectives described herein, and objectives which are not described above will be clearly understood by those skilled in the art from the following descriptions.

A display device according to embodiments of the present disclosure includes: a display panel including a display area and an optical area, and a sensor arranged to correspond to the optical area, wherein the display panel includes: a substrate; a circuit layer arranged on the substrate; an anode electrode arranged on the circuit layer; an organic compound layer arranged on the anode electrode and including a light-emitting area; a cathode electrode and a pattern layer arranged on the organic compound layer; an encapsulation layer arranged on the cathode electrode and the pattern layer; a touch sensor layer arranged on the encapsulation layer; and a plurality of lenses configured to overlap the pattern layer.

The display device according to embodiments of the present disclosure can block the path of lateral leakage current by using the lens arranged within the display panel.

The display device according to embodiments of the present disclosure can provide a path, which reduces the generation of light caused by lateral leakage current, through an arrangement relationship between lenses and cathode electrodes arranged within the display panel.

The display device according to embodiments of the present disclosure can prevent or reduce the generation of light caused by lateral leakage current, thereby improving the performance of an optical device (or sensor). Accordingly, low-power operation of the sensor can be made possible.

A display panel according to embodiments of the present disclosure includes a display area and an optical area, wherein the display panel comprises: a substrate; a circuit layer arranged on the substrate; an anode electrode arranged on the circuit layer; an organic compound layer arranged on the anode electrode and including a light-emitting area; a cathode electrode and a pattern layer arranged on the organic compound layer; an encapsulation layer arranged on the cathode electrode and the pattern layer; a touch sensor layer arranged on the encapsulation layer; and a plurality of lenses configured to overlap the pattern layer.

Various useful advantages and effects of the embodiments are not limited to the above-described contents and will be more easily understood from descriptions of the specific embodiments.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, in which:

FIG. 1 is a view showing a display panel and a display panel driver of a display device according to an embodiment of the present disclosure;

FIG. 2 is a view showing a display area and an optical area of the display panel according to an embodiment of the present disclosure;

FIG. 3 is a cross-sectional view schematically showing the display panel according to an embodiment of the present disclosure;

FIG. 4 is a cross-sectional view showing a cross-sectional structure of a pixel area arranged in the display area of the display panel according to an embodiment of the present disclosure;

FIG. 5 is a view schematically showing a cross-sectional structure of a pixel area and a light-transmitting area arranged in the optical area of the display device according to an embodiment of the present disclosure;

FIG. 6 is an enlarged view of area A in FIG. 2 showing an arrangement relationship between light-emitting elements and lenses;

FIG. 7 is an enlarged view of area A in FIG. 2 showing an arrangement relationship among light-emitting elements, lenses, and cathode electrodes; and

FIG. 8 is a cross-sectional view taken along line I-I′ in FIG. 7.

### DETAILED DESCRIPTION OF EMBODIMENTS

The advantages and features of the present disclosure and methods for accomplishing the same will be more clearly understood from embodiments described below with reference to the accompanying drawings. However, the present disclosure is not limited to the following embodiments but can be implemented in various different forms. Rather, the present embodiments will make the disclosure of the present disclosure complete and allow those skilled in the art to completely comprehend the scope of the present disclosure. The present disclosure is only defined within the scope of the accompanying claims.

Shapes, sizes, ratios, angles, numbers, and the like disclosed in the drawings for describing the embodiments of the present disclosure are examples, and the present disclosure is not limited to the illustrated items. Like reference numerals refer to like elements throughout. In addition, in describing the present disclosure, if it is determined that the detailed description of the related known technology can unnecessarily obscure the subject matter of the present disclosure, the detailed description thereof will be omitted.

The terms such as “comprising”, “including”, “having” and “consisting of” used herein are generally intended to allow other components to be added unless the terms are used with the term “only”. References to the singular shall be construed to include the plural unless expressly stated otherwise. Further, the term “can” fully encompasses all the meanings and coverages of the term “may” and vice versa.

In interpreting a component, it is interpreted to include an error range even if there is no separate description.

In the case of a description of a positional relationship, for example, when the positional relationship of two parts is described as ‘on,’ ‘at an upper portion,’ ‘at a lower portion,’ ‘next to,’ and the like, one or more other parts can be located between the two parts unless ‘immediately’ or ‘directly’ is used.

In the description for the embodiments, the first, second, etc. are used to describe various components, but these components are not limited by these terms. These terms are only used to distinguish one component from another. Therefore, the first component mentioned below can be a second component within the technical spirit of the present disclosure.

Throughout the specification, the same reference numerals refer to the same component.

The features of each of the various embodiments of the present disclosure can be combined or combined with each another, in whole or in part, and various technical interlocking and driving can be possible, and each of the embodiments can be implemented independently of each other or in conjunction with each other.

Recently, one of the importances of a display device as a visual information transmission medium has been further emphasized in information-oriented society, and display devices are being improved to meet requirements, such as low power consumption, reduction of thickness, weight reduction, high definition, high efficiency, and the like.

A display device according to one or more embodiments of the present disclosure can enhance the performance of a sensor by preventing light having an adverse effect on the sensor from entering the sensor through a lens structure arranged in a display panel. Accordingly, the display device enables low-power operation through the enhanced performance of the sensor. All the components of each display device/apparatus according to all embodiments of the present disclosure are operatively coupled and configured.

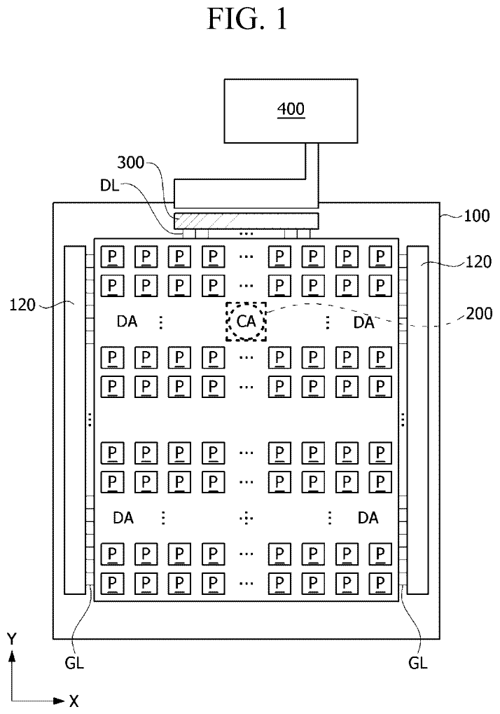

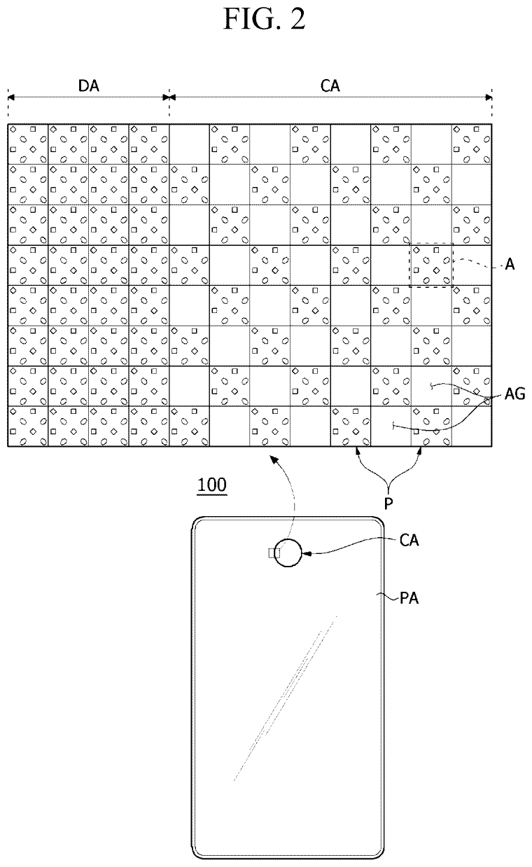

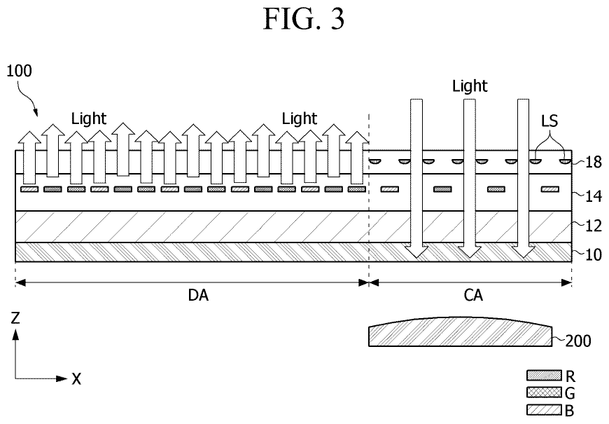

FIG. 1 is a view showing a display panel and a display panel driver of a display device according to an embodiment of the present disclosure. FIG. 2 is a view showing a display area and an optical area of the display panel according to an embodiment of the present disclosure. FIG. 3 is a cross-sectional view schematically showing the display panel according to an embodiment of the present disclosure.

Referring to FIGS. 1 to 3, the display device according to an embodiment of the present disclosure can include a display panel 100 and an optical device 200. In addition, the display device can further include a case configured to protect the display panel 100 and the optical device 200.

The display panel 100 can implement a full-screen display. In addition, the optical device 200 can include an image sensor (or camera), a proximity sensor, a white light illumination element, an optical element for facial recognition, and the like. For example, the optical device 200 can include at least one of an image sensor, a proximity sensor, a illuminance sensor, a gesture sensor, a motion sensor, a fingerprint recognition sensor, or a biometric sensor.

The display panel 100 can include a display area DA and an optical area CA in which the optical device 200 is correspondingly arranged. In addition, both the display area DA and the optical area CA can output an image, and thus the display area DA can be a first display area and the optical area CA can be a second display area.

The display area DA and the optical area CA can have different luminance. Here, luminance can refer to the luminous intensity of light emitted in a particular direction. In addition, gradation can refer to tone levels ranging from the darkest to the lightest part of an image, and can be represented within a range from 0 to 255 in 8-bit data. For example, in an RGB color space, pixel data (R=255, G=255, B=255) represents a gradation value that implements the luminance of peak white. Peak white can correspond to the maximum luminance that the display device is capable of expressing. When pixel data with the same gradation value—for example, a peak white gradation value of ‘255’—is written to pixels in the display area DA and the optical area CA of the display device, the luminance values of the display area DA and the optical area CA can differ.

The display area DA and the optical area CA can have different resolutions. For example, the resolution of a plurality of pixels arranged in the optical area CA can be lower than the resolution of a plurality of pixels arranged in the display area DA. As the resolution of the plurality of pixels arranged in the optical area CA decreases, a sufficient amount of light can be injected into the optical device 200 arranged in the optical area CA. However, the resolutions of the display area DA and the optical area CA are not necessarily limited thereto, and can be the same if the optical area CA has sufficient light transmittance or if an appropriate noise compensation algorithm is implemented. Here, the pixels arranged in the display area DA can be first pixels, and the pixels arranged in the optical area CA can be second pixels.

The optical area CA can be an area in which the optical device 200 is arranged. Since the optical area CA overlaps various sensors or the like, the optical area CA can have a relatively smaller area than the display area DA, which outputs most of an image.

The optical area CA can be arranged at various positions where incidence of light is required. For example, as shown in FIG. 2, the optical area CA can be arranged at an upper central portion of the display area, but the position of the optical area CA is not necessarily limited thereto. The optical area CA can be arranged at an upper left or right portion of the display area. In addition, the optical area CA can be arranged across the entire upper portion of the display area. In addition, the optical area CA can be arranged at a central portion or lower portion of the display area.

The display area DA and the optical area CA can include a pixel array in which pixels to which pixel data are written are arranged. To secure light transmittance of the optical area CA, pixels per inch (PPI) of the optical area CA can be lower than the PPI of the display area DA.

The pixel array of the display area DA can include a pixel area, having a high PPI, in which a plurality of pixels are arranged. In addition, the pixel array of the optical area CA can include a pixel area, having a relatively low PPI, in which a plurality of pixels are arranged to be spaced apart from one another by a light-transmitting area. In the optical area CA, external light can pass through the display panel 100 through a light-transmitting area having high light transmittance and be received by an optical device (or sensor) positioned below the display panel 100.

Since both the display area DA and the optical area CA include pixels, an input image can be reproduced on the display area DA and the optical area CA.

Each of the pixels in the display area DA and the optical area CA can include sub-pixels of different colors to implement color in an image. The sub-pixels can include a red sub-pixel, a green sub-pixel, and a blue sub-pixel. Each of the pixels can further include a white sub-pixel. In addition, each of the sub-pixels can include a pixel circuit and a light-emitting element. Here, the sub-pixels arranged in the display area DA can be first sub-pixels, and the sub-pixels arranged in the optical area CA can be second sub-pixels. In addition, the light-emitting element can be implemented as an organic light-emitting diode OLED.

The optical area CA can include pixels, and pixel data of the input image can be written to the pixels in a display mode so as to display the input image. In this case, since the optical devices 200 are arranged below a rear surface of the display panel 100 so as to overlap the optical area CA, a display area of a screen is not restricted by the optical devices 200. Accordingly, the display device according to embodiments of the present disclosure can expand the display area of the screen to implement a full-screen display and increase the degree of freedom in screen design.

The optical area CA can include a plurality of light-transmitting areas AG arranged between a plurality of the second pixels. Specifically, the optical area CA can include pixels P spaced apart a predetermined distance from each other and the light-transmitting area AG arranged between adjacent pixels P. Sub-pixels of the pixels P can be spaced apart from each other within the pixel area of the optical area CA. Here, the area in which the pixels P are arranged can represent the pixel area.

External light can be received by the optical device 200 through the light-transmitting area AG. Here, the light-transmitting area AG can include transparent media having high light transmittance to allow light to be incident with minimal light loss. For example, the light-transmitting area AG can be made of a transparent insulating material without including a metal wire or pixels. Accordingly, the light transmittance of the optical area CA can increase as the light-transmitting area AG becomes larger.

A shape of the light-transmitting area AG is exemplified as a rectangle, but is not limited thereto. For example, the light-transmitting area AG can be designed in various shapes such as circular, oval, and polygonal shapes.

The optical area CA can include a lens LS. In addition, some components of the display panel 100 constituting a path along which lateral leakage current flows can be electrically disconnected by emitting a laser through the lens LS. Accordingly, the generation of light caused by lateral leakage current in the display device can be prevented.

A camera module can be provided as the optical device 200, and the camera module can capture an external image in an imaging mode and output photo or moving image data. A lens of the camera module can face the optical area CA. In addition, the external light can be incident to a lens of the camera module through the optical area CA, and the lens of the camera module can condense light onto an image sensor omitted from the drawings. Accordingly, the camera module can output photo or moving image data by capturing an external image in the imaging mode.

In addition, the camera module provided as the optical device 200 can be an infrared camera including an infrared sensor. Here, the infrared camera captures dot beams of infrared wavelengths focused on a person's face. In addition, the infrared camera can generate facial pattern data by converting light of an infrared wavelength passing through the display panel 100 into electrical signals and converting them into digital data. Accordingly, when the infrared-rays irradiated from an infrared illuminator are irradiated to the user's face and the infrared-rays reflected from the face are received by the infrared camera, a biometric authentication module of a host system processes the user's authentication. In this case, the infrared illuminator can enable face recognition even in a dark environment by using a flood illuminator that generates an infrared (IR) flash.

Meanwhile, in order to secure the light transmissivity, some pixels can be removed from the optical area CA compared to the display area DA. In addition, a picture quality compensation algorithm to compensate for the luminance and color coordinates of the pixels disposed in the optical area CA due to the removed pixels can be applied to the display device, but is not necessarily limited thereto.

In the present disclosure, low-resolution pixels can be disposed in the optical area CA. Therefore, since the display area of the screen is not limited due to the camera module, a full-screen display can be implemented.

The display panel 100 can have a width in the X-axis direction, a length in the Y-axis direction, and a thickness in the Z-axis direction. Here, the width and length of the display panel 100 can be set to various design values depending on application fields of the display device. In addition, the X-axis direction can mean a width direction or a horizontal direction, the Y-axis direction can mean a longitudinal direction or a vertical direction, and the Z-axis direction can mean a vertical direction, a stacking direction, or a thickness direction. Here, the X-axis direction, the Y-axis direction, and the Z-axis direction can be perpendicular to each other, but can also mean different directions that are not perpendicular to each other. Each of the X-axis direction, the Y-axis direction, and the Z-axis direction can be described as one of a first direction, a second direction, or a third direction. Further, the plane extended in the X-axis direction and the Y-axis direction can mean a horizontal plane.

The display panel 100 can include a circuit layer 12 disposed on the substrate 10 and a light-emitting element layer 14 disposed on the circuit layer 12. In addition, the display panel 100 can include a encapsulation layer 16 disposed on the light-emitting element layer 14 and a touch sensor layer 18 disposed on the encapsulation layer 16.

The substrate 10 can be formed of an insulating material or a material having flexibility. For example, the substrate 10 can be made of glass, metal, or plastic, but is not limited thereto.

The circuit layer 12 can include a pixel circuit connected to wirings such as data lines, gate lines, and power lines, a gate driver connected to the gate lines, and the like. Further, the circuit layer 12 can include transistors implemented with thin film transistors (TFTs) and circuit elements such as capacitors or the like. Here, the wirings and circuit elements of the circuit layer 12 can be implemented with a plurality of insulating layers, two or more metal layers separated with the insulating layer interposed therebetween, and an active layer including a semiconductor material.

The light-emitting element layer 14 can include a light-emitting element driven by a pixel circuit. Here, the light-emitting element can be implemented with an organic light emitting diode (OLED). The OLED can include an organic compound layer formed between an anode and a cathode. The organic compound layer includes a hole injection layer (HIL), a hole transport layer (HTL), an emission layer (EML), an electron transport layer (ETL), and an electron injection layer (EIL), but is not limited thereto. When a voltage is applied to an anode and an cathode of the OLED, the holes passing through the hole transport layer (HTL) and the electrons passing through the electron transport layer (ETL) can be moved to the light emitting layer (EML) to form excitons and emit visible light from the light emitting layer (EML).

The light-emitting element layer 14 can further include a color filter array disposed on the pixels to selectively transmit red, green, and blue wavelengths.

The light-emitting element layer 14 can be covered by a protective film, and the protective film can be covered by an encapsulation layer. Here, the protective film can have a structure in which organic films and inorganic films are alternately stacked. In this case, the inorganic film can block penetration of moisture or oxygen. In addition, the organic film can planarize the surface of the inorganic film. When the organic film and the inorganic film are stacked in multiple layers, a movement path of moisture or oxygen is longer than that of a single layer, so that the penetration of moisture/oxygen affecting the light-emitting element layer 14 can be effectively blocked.

The encapsulation layer 16 covers the light-emitting element layer 14 so as to seal the circuit layer 12 and the light-emitting element layer 14. Here, the encapsulation layer 16 can have a multi-insulation film structure in which the organic film and the inorganic film are alternately stacked. In this case, the inorganic film blocks penetration of moisture or oxygen. In addition, the organic film planarizes the surface of the inorganic film. When the organic film and the inorganic film are stacked in multiple layers, the movement path of moisture or oxygen is longer than that of a single layer, so that the penetration of moisture/oxygen affecting the light-emitting element layer 14 can be effectively blocked.

The touch sensor layer 18 can include capacitive touch sensors that sense a touch input based on a change in capacitance before and after the touch input. The touch sensor layer 18 can include metal wiring patterns and insulating films forming capacitance of the touch sensors. The insulating films can insulate portions in which the metal wiring patterns are intersected and planarize the surface of the touch sensor layer.

A polarizing plate omitted in the drawing can be adhered on the touch sensor layer 18. The polarizing plate can improve visibility and contrast ratio by converting polarization of external light reflected by the metal patterns of the circuit layer 12. Further, a cover glass omitted from the drawings can be adhered on the polarizing plate.

The color filter layer can be formed on the touch sensor layer 18. The color filter layer can include red, green, and blue color filters. In addition, the color filter layer can further include a black matrix pattern. The color filter layer can absorb some wavelengths of light reflected from the circuit layer 12 to replace the role of a polarizing plate and increase color purity. A cover glass omitted in the drawings can be adhered on the color filter layer.

The color filter layer can include an organic film covering the color filter and the black matrix pattern. An extended portion of the organic film can cover the remaining inorganic film or the substrate 10 in the bezel area, for example, the edge area of the display panel 100.

The display device according to embodiment of the present disclosure can include the display panel 100 having a pixel array arranged on a screen, the display panel driver, etc.

The pixel array of the display panel 100 can include data lines DL, gate lines GL intersecting the data lines DL, and pixels connected to the data lines DL and gate lines GL and arranged in a matrix.

The pixel array can be divided into a circuit layer 12 and a light-emitting element layer 14, as shown in FIG. 3. Then, a touch sensor array can be arranged on the light-emitting element layer 14. Here, each of the pixels of the pixel array can include two to four sub-pixels, but is not necessarily limited thereto. Each of the sub-pixels can include a pixel circuit arranged in the circuit layer 12.

Each of the sub-pixels of the display area DA and the optical area CA can include a pixel circuit. The pixel circuit can include a driving element to supply current to the light-emitting element (OLED), a plurality of switching elements to sample a threshold voltage of the driving element and switch a current path of the pixel circuit, a capacitor to maintain a gate voltage of the driving element, etc. In this case, the pixel circuit can be arranged below the light-emitting element.

The display panel driver can write pixel data of an input image into the pixels P. The pixels P can be interpreted as a pixel group including a plurality of sub-pixels P.

The display panel driver can include a data driver that supplies a data voltage of pixel data to the data lines DL and a gate driver 120 that sequentially supplies gate pulses to the gate lines GL. Further, the data driver can be integrated into the drive IC 300. In addition, the display panel driver can further include a touch sensor driver omitted from the drawings.

The drive IC 300 can be bonded on the display panel 100. The drive IC 300 receives pixel data of an input image and a timing signal from the host system 400, supplies a data voltage of the pixel data to pixels, and synchronizes the data driver and the gate driver 120.

The drive IC 300 can be connected to the data lines DL through data output channels to supply data voltages of pixel data to the data lines DL. The drive IC 300 can output a gate timing signal for controlling the gate driver 120 through gate timing signal output channels.

The gate driver 120 can include a shift register formed on a circuit layer of the display panel 100 together with a pixel array. The shift register of the gate driver 120 can sequentially supply gate signals to the gate lines GL under the control of the timing controller. The gate signal can include a scan pulse and an EM pulse of an emission signal.

The host system 400 can be implemented with an application processor (AP). The host system 400 can transmit pixel data of an input image to the drive IC 300 through a mobile industry processor interface (MIPI). The host system 400 can be connected to the drive IC 300 through a flexible printed circuit, for example, a flexible printed circuit (FPC).

Meanwhile, the display panel 100 can be implemented with a flexible panel applicable to a flexible display.

The flexible panel can be made of a so-called “plastic OLED panel”. The plastic OLED panel can include a back plate and a pixel array on an organic thin film adhered on the back plate. A touch sensor array can be formed over the pixel array.

The back plate can be a polyethylene terephthalate (PET) substrate. The pixel array and the touch sensor array can be formed on the organic thin film. The back plate can block moisture permeation toward the organic thin film so that the pixel array is not exposed to humidity.

The organic thin film can be a polyimide (PI) substrate. A multi-layered buffer film can be formed on the organic thin film with an insulating material. Further, the circuit layer 12 and the light-emitting element layer 14 can be stacked on the organic thin film.

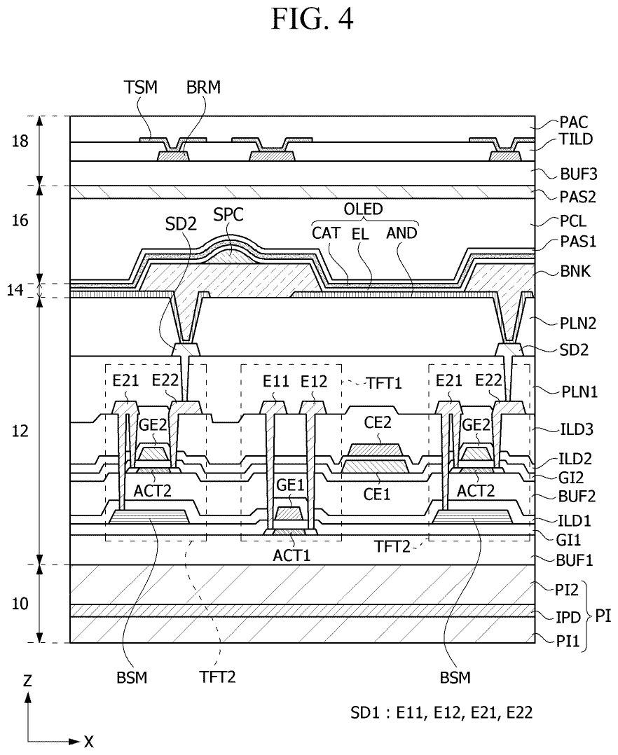

FIG. 4 is a cross-sectional view of a cross-sectional structure of a pixel area disposed in a display area in a display panel according to one embodiment of the present invention. Here, it should be noted that the cross-sectional structure of the pixel area is not limited to that of FIG. 4. In FIG. 4, TFT can represent a driving element of the pixel circuit. In detail, TFT1 can be a first TFT that is one of LTPS TFTs disposed in the display area, and TFT2 can be a second TFT that is one of oxide TFTs disposed in the display area.

Referring to FIG. 4, a plurality of pixel circuits and wires connected to the pixel circuits can be disposed in the display area DA of the display panel 100. Here, the pixel circuits of the display area can include a pixel circuit of a red sub-pixel driving a red light-emitting element, a pixel circuit of a green sub-pixel driving a green light-emitting element, and a pixel circuit of a blue sub-pixel driving a blue light-emitting element. Further, the pixel circuits can be separated into a plurality of circuit areas along the X-axis direction of the display panel 100 within the display area DA.

The substrate PI can include first and second substrates PI1 and PI2. In addition, an inorganic film IPD can be formed between the first substrate PI1 and the second substrate PI2. In this case the inorganic film IPD can block moisture permeation. Here, since the substrate PI can be formed of polyimide, it can be referred to as a PI substrate, and the first and second substrates PI1 and PI2 can be referred to as first and second PI substrates.

The first buffer layer BUF1 can be formed on the second substrate PI2. The first buffer layer BUF1 can be formed of a multi-layered insulating layer in which two or more oxide layers SiO₂ and nitride layers SiNx are stacked. A first semiconductor layer is formed on the first buffer layer BUF1. The first semiconductor layer can include a polysilicon semiconductor layer patterned in a photolithography process. The first semiconductor layer can include a polysilicon active pattern ACT1 forming a semiconductor channel in the first TFT TFT1.

A first gate insulating layer GI1 is deposited on the first buffer layer BUF1 to cover the active pattern ACT1 of the first semiconductor layer. The first gate insulating layer GI1 includes an inorganic insulating material layer. A first metal layer is formed on the first gate insulating layer GI1. The first metal layer is insulated from the first semiconductor layer by the first gate insulating layer GI1.

The first metal layer can include a single metal layer patterned in a photolithography process or metal patterns in which two or more metal layers are stacked. The first metal layer can include the gate electrode GE1 of the first TFT TFT1 and a light shield pattern BSM under the second TFT TFT 2.

A first interlayer insulating layer ILD1 is formed on the first gate insulating layer GI1 to cover the patterns of the first metal layer. The first interlayer insulating layer ILD1 can include an inorganic insulating material. A second buffer layer BUF2 is formed on the first interlayer insulating layer ILD1. The second buffer layer BUF2 can include a single layer or a multi-layer inorganic insulating material.

The second semiconductor layer can include an oxide semiconductor pattern ACT2 forming a semiconductor channel in the second TFT TFT2. The second gate insulating layer GI2 can be deposited on the second buffer layer BUF2 to cover the active pattern ACT2 of the second semiconductor layer. The second gate insulating layer GI2 can include a single or multi-layered inorganic insulating material. A second metal layer can be formed on the second gate insulating layer GI2. The second metal layer can be insulated from the second semiconductor layer by the second gate insulating layer GI2.

The second metal layer can include a single metal layer patterned in a photolithography process or metal patterns in which two or more metal layers are stacked. The second metal layer can include a gate electrode GE2 of the second TFT TFT2 and a lower capacitor electrode CE1.

A second interlayer insulating layer ILD2 can be formed on the second gate insulating layer GI2 to cover the patterns of the second metal layer. The second interlayer insulating layer ILD2 can include a single layer or a multi-layer inorganic insulating material. A third metal layer can be formed on the second interlayer insulating layer ILD2. The third metal layer can be insulated from the second metal layer by the second interlayer insulating layer ILD2.

The third metal layer can include a single metal layer patterned in a photolithography process or metal patterns in which two or more metal layers are stacked. The third metal layer can include an upper capacitor electrode CE2. The capacitor Cst of the pixel circuit can be composed of the upper capacitor electrode CE2, the lower capacitor electrode CE1, and a dielectric layer therebetween, for example, the second interlayer insulating layer TLD2.

A third interlayer insulating layer ILD3 covering the patterns of the third metal layer can be formed on the second interlayer insulating layer ILD2. The third interlayer insulating layer ILD3 can include a single layer or a multi-layer inorganic insulating material. A fourth metal layer can be formed on the third interlayer insulating layer ILD3. The fourth metal layer can be insulated from the second semiconductor layer by the second gate insulating layer GI2.

A fourth metal layer SD1 can include a single metal layer patterned in a photolithography process or metal patterns in which two or more metal layers are stacked. The fourth metal layer can include first and second electrodes E11 and E12 of the first TFT TFT1 and first and second electrodes E21 and E22 of the second TFT TFT2. The first and second electrodes E11 and E12 of the first TFT TFT1 can be connected to a first active pattern ACT1 through a first contact hole passing through the insulating layers GI1, ILD1, BUF2, GI2, ILD2 and ILD3. The first and second electrodes E21 and E22 of the second TFT TFT2 can be connected to a second active pattern ACT2 through a second contact hole passing through the insulating layers GI2, ILD2 and ILD3. The first electrode E21 of the second TFT TFT2 can be connected to the light shield pattern BSM through a third contact hole passing through the insulating layers ILD1, BUF2, GI2, ILD2 and ILD3. Here, a strong electric field can be generated in the metal patterns E11, E12, E21 and E22 of the fourth metal layer due to voltages swinging between a gate-on voltage and a gate-off voltage with a large voltage difference.

A first planarization layer PLN1 can cover the metal patterns E11, E12, E21 and E22 of the fourth metal layer. The first planarization layer PLN1 can thickly cover the display area DA of the circuit layer 12 with an organic insulating material. When the first planarization layer PLN1 is applied on the circuit layer 12, the organic insulating material can flow to the edge of the display panel 100 and cover the side surface of the circuit layer 12.

A fifth metal layer can be formed on the first planarization layer PLN1. The fifth metal layer can be insulated from the fourth metal layer by the first planarization layer PLN1. The fifth metal layer can include a single metal layer patterned in a photolithography process or metal patterns in which two or more metal layers are stacked. The fifth metal layer can include a metal pattern SD2 connecting the light-emitting element to the second TFT TFT2. The metal pattern SD2 can be connected to the second electrode E22 of the second TFT TFT2 through a fourth contact hole penetrating the first planarization layer PLN1.

A second planarization layer PLN2 can be formed on the first planarization layer PLN1 to cover the metal patterns of the fifth metal layer. The second planarization layer PLN2 can thickly cover the display area DA of the circuit layer 12 with an organic insulating material. A sixth metal layer can be formed on the second planarization layer PLN2. The second planarization layer PLN2 can planarize the surface on which the sixth metal layer is formed.

The sixth metal layer can include a single metal layer patterned in a photolithography process or metal patterns in which two or more metal layers are stacked. The pattern of the sixth metal layer can include an anode electrode AND of the light emitting device. The anode electrode AND can be in contact with the metal pattern SD2 connected to the second TFT TFT2 of the pixel circuits through the fifth contact hole penetrating the second planarization layer PLN2.

In the light emitting element layer 14, a bank BNK can be formed on the second planarization layer PLN2 to cover the edge of the anode AND. In this case, the bank BNK can be formed in a pattern that divides a light emitting area (or an opening area) from which light is emitted from each pixel to the outside. Accordingly, the bank BNK can be referred to as a pixel-defining film. The bank BNK can be patterned in a photolithography process by including an organic insulating material having photosensitivity. Further, a spacer SPC having a predetermined height can be formed on the bank BNK. In this case, the bank BNK and the spacer SPC can be integrated with the same organic insulating material. Further, the spacer SPC secures a gap between a fine metal mask (FMM) and the anode electrode AND so that the FMM is not in contact with the anode electrode AND during a deposition process of the light emitting device formed of an organic compound.

A seventh metal layer used as a cathode electrode CAT of the light-emitting element can be formed on the bank BNK and an organic compound layer EL. The seventh metal layer can be connected between sub-pixels in the display area DA. Here, the organic compound layer EL can be referred to as a light emitting layer or an electroluminescent layer.

The encapsulation layer 16 can include multiple insulating layers covering the cathode electrode CAT of the light emitting device. The multiple insulating layers can include a first inorganic insulating layer PAS1 covering the cathode electrode CAT, a thick organic insulating layer PCL covering the first inorganic insulating layer PAS1, and a second inorganic insulating layer PAS2 covering the organic insulating layer PCL.

The touch sensor layer 18 can include a third buffer layer BUF3 covering the second inorganic insulating layer PAS2, a bridge metal BRM arranged on the third buffer layer BUF3, a touch interlayer insulating layer TILD of an inorganic material covering the bridge metal BRM, a touch sensor metal TSM arranged above the bridge metal BRM, and an organic insulating layer PAC covering the touch interlayer insulating layer TILD and the touch sensor metal TSM. Here, the third buffer layer BUF3 can be a touch buffer layer.

An eighth metal layer used as the bridge metal BRM can be arranged on the third buffer layer BUF3 and can overlap the bank BNK. The eighth metal layer can include a single-metal layer or a stacked-metal layer, comprising two or more metal layers, patterned through the photolithography process.

The ninth metal layer can include a single-metal layer or a stacked-metal layer, comprising two or more metal layers, patterned through the photolithography process. A pattern of the ninth metal layer can include the touch sensor metal TSM. The touch sensor metal TSM can be contacted to the bridge metal BRM through a sixth contact hole through the touch interlayer insulating layer TILD.

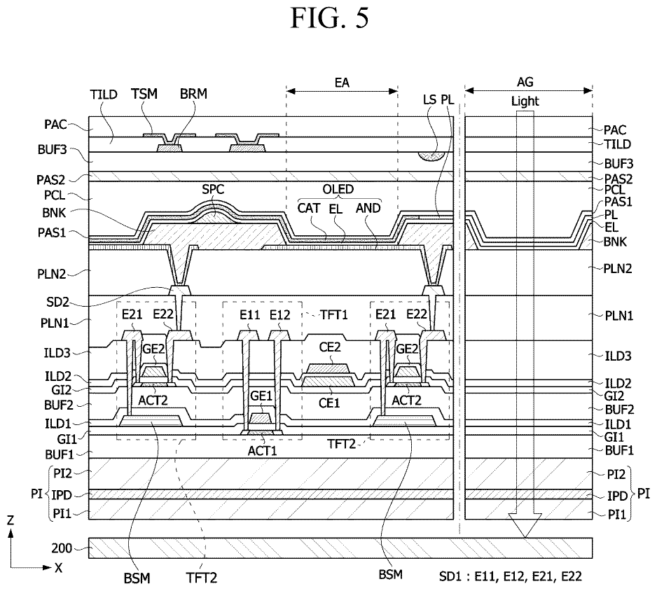

FIG. 5 is a view schematically showing a cross-sectional structure of a pixel area and a light-transmitting area arranged in the optical area of the display device according to an embodiment of the present disclosure. Here, the cross-sectional structure of the pixel area is not necessarily limited to the cross-sectional structure shown in FIG. 5.

Referring to FIG. 5, the optical area CA can include a pixel area and the light-transmitting area AG.

The pixel area of the optical area CA can include a substrate PI, a circuit layer 12 on the substrate PI, a light-emitting element layer 14 on the circuit layer 12, an encapsulation layer 16 on the light-emitting element layer 14, and a touch sensor layer 18 on the encapsulation layer 16. The substrate PI, the circuit layer 12, the light-emitting element layer 14, the encapsulation layer 16, and the touch sensor layer 18 arranged in the pixel area of the optical area CA are substantially the same in structural arrangement as the pixel area of the display area DA described in FIG. 4. Accordingly, the same reference numerals are assigned thereto, and the same description thereof can be omitted or provided in a simplified manner.

The pixel area of the optical area CA can be an area in which a plurality of sub-pixels are arranged, and the plurality of sub-pixels can generate light. For example, when power is applied to the organic compound layer EL, the organic compound layer EL can generate light. In this case, an area in which light is generated in the organic compound layer EL can be a light-emitting area EA.

The light-transmitting area AG can include transparent media having high light transmittance and no metal to allow light to be incident with minimal light loss. The light-transmitting area AG can be formed of a transparent insulating material without including a metal wire or pixels. For example, compared to the pixel area, a metal wire such as the anode electrode AND and the cathode electrode CAT may not be arranged in the light-transmitting area AG. In addition, the organic compound layer EL can be arranged in the light-transmitting area AG.

The light-transmitting area AG can include a separate pattern layer PL to prevent deposition of the cathode electrode CAT.

The pattern layer PL can be arranged on the organic compound layer EL, and can be formed, together with the cathode electrode CAT, as a single layer. Accordingly, when the cathode electrode CAT is deposited, the pattern layer PL can prevent the cathode electrode CAT from being deposited on the light-transmitting area AG. For example, when the cathode electrode CAT is deposited, the metal constituting the cathode electrode CAT can accumulate in an area where the cathode patterning material, which is the material of the pattern layer PL, is absent, thereby forming a pattern (cathode electrode pattern). The pattern layer PL can be used as a pattern for a cathode electrode deposited to form a predetermined pattern. Accordingly, a side surface of the pattern layer PL can be in contact with the cathode electrode CAT. Here, the metal constituting the cathode electrode CAT can be, but is not necessarily limited to, a magnesium-silver (Mg—Ag) alloy. In addition, the pattern layer PL can include, but is not necessarily limited to, a non-metallic material. For example, the pattern layer PL can include an organic material as a fluorine-based non-metallic material. In addition, the pattern layer PL can also include a metal material, taking into account the transmittance of the light-transmitting area AG, the transmittance of a laser, or the like.

In the pixel area of the optical area CA, a portion of the pattern layer PL can be arranged on the bank BNK. Accordingly, a portion of the cathode electrode CAT can be arranged, together with the pattern layer PL, on the bank BNK. In addition, the pattern layer PL of the pixel area can extend into the light-transmitting area AG. In addition, the organic compound layer EL of the pixel area arranged in the optical area CA can extend into the light-transmitting area AG. Accordingly, the pattern layer PL can be arranged on the organic compound layer EL in the light-transmitting area AG.

Light can be generated by lateral leakage current in the optical area CA. In addition, the light generated by lateral leakage current can affect the optical device 200. For example, since the optical area CA includes the light-transmitting area AG having high transmittance, the light generated by lateral leakage current can affect the optical device 200 through the light-transmitting area AG. For example, for an image sensor, the light can cause color distortion in an image. Alternatively, for an infrared sensor, the light can cause an error in identifying a target object (such as a face).

The display device according to an embodiment of the present disclosure can prevent or minimize the generation of light caused by lateral leakage current by blocking lateral leakage current through a structural improvement of the display panel 100, or by increasing the length of a path along which the lateral leakage current flows. Accordingly, the display device according to an embodiment of the present disclosure can prevent or minimize the generation of light caused by lateral leakage current.

At least one of the components of the display panel 100 constituting a path along which lateral leakage current flows can be electrically disconnected by emitting a laser onto a predetermined position through the lens LS arranged on the display panel 100. Here, the path of lateral leakage current flowing through the organic compound layer EL in the optical area CA can be a first path.

Since the lateral leakage current can flow through the organic compound layer EL, some components of the organic compound layer EL can be electrically disconnected by a laser process using the lens LS. For example, the hole transport layer HTL of the organic compound layer EL where a p-dopant is arranged can be electrically disconnected by the laser process using the lens LS. Accordingly, some components of the organic compound layer EL that are disconnected by the laser can serve as a barrier against lateral leakage current. Accordingly, the display device according to an embodiment of the present disclosure can prevent the generation of light caused by lateral leakage current by using the barrier structure to block the lateral leakage current from flowing through the organic compound layer EL. In this case, the cathode electrode CAT, formed of a metal material, can block the laser that has passed through the lens LS from reaching the organic compound layer EL, and accordingly, that the laser that has passed through the lens LS can be emitted onto the organic compound layer EL through the pattern layer PL.

Although lateral leakage current can primarily flow through the hole transport layer HTL of the organic compound layer EL including the p-dopant, the possibility of lateral leakage current flowing through the cathode electrode CAT may not be excluded.

Accordingly, the cathode electrode CAT constituting the light-emitting element OLED can be provided in the display panel 100 in a structure that prevents or minimizes the generation of light caused by lateral leakage current. For example, in the display area DA, the cathode electrode CAT can be arranged throughout the entire display area of the display area DA. In addition, unlike the cathode electrode CAT in the display area DA, the cathode electrode CAT in the optical area CA can be patterned using the pattern layer PL so as to bypass the light-transmitting area AG. In this case, the cathode electrode CAT in the pixel area arranged in the optical area CA can be patterned along a path that prevents or minimizes the generation of light caused by lateral leakage current. Here, the path of the lateral leakage current flowing through the cathode electrode CAT in the pixel area of the optical area CA can be a second path.

Accordingly, each of two light-emitting elements OLED arranged adjacent to each other can include a connection portion of the cathode electrode CAT; and by arranging the two connection portions as far apart as possible, the length of the path through which the lateral leakage current flows can be increased. Accordingly, the display device according to an embodiment of the present disclosure can prevent or minimize the generation of light caused by lateral leakage current. In this case, the two light-emitting elements OLED arranged adjacent (or in close proximity) to each other can emit light of different colors. For example, one of the two light-emitting elements OLED arranged adjacent to each other can be a blue light-emitting element and the other can be a red light-emitting element. However, if the two light-emitting elements OLED arranged adjacent to each other are light-emitting elements that Implement the same color, the effect of light generated by lateral leakage current can be relatively weaker than the effect of the two light-emitting elements OLED arranged adjacent to each other that emit light of different colors. However, even when the two light-emitting elements OLED arranged adjacent to each other implement the same color, considering the time it takes for lateral leakage current to reach the light-emitting elements OLED and the resulting delayed emission of the light-emitting elements OLED, the arrangement structure of the cathode electrode CAT according to an embodiment of the present disclosure can be efficient in terms of preventing or minimizing the generation of light caused by lateral leakage current.

A structure of the display panel 100 that can block lateral leakage current or, even when the lateral leakage current flows, minimize the generation of light caused by lateral leakage current will be described below.

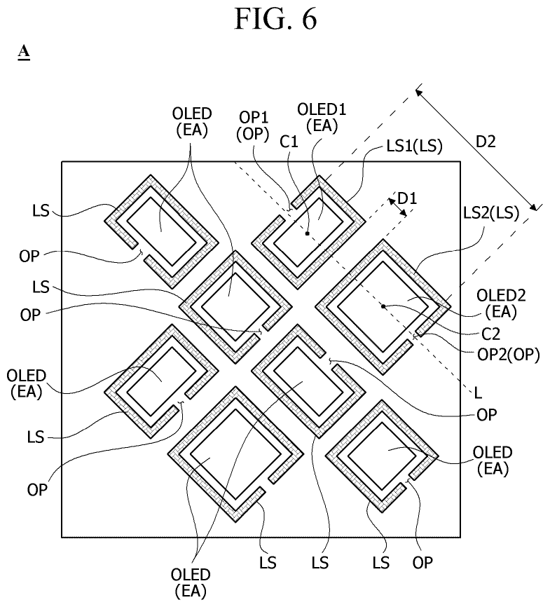

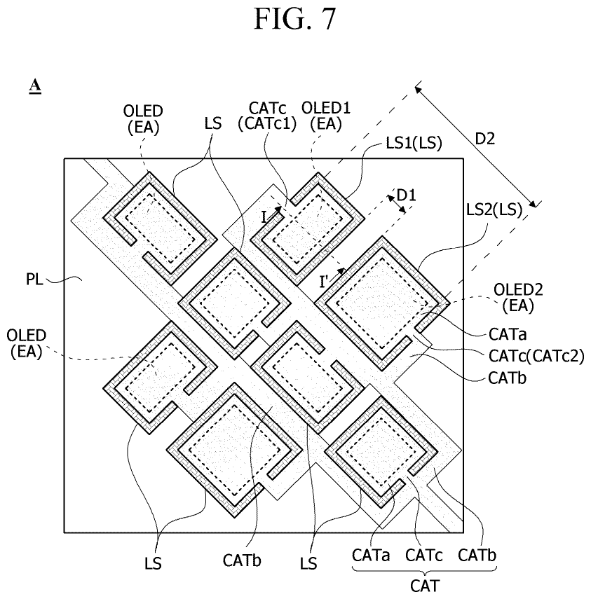

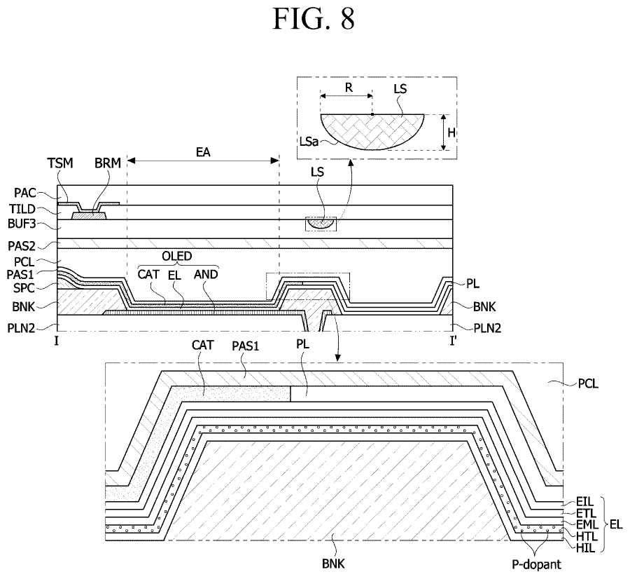

FIG. 6 is an enlarged view showing area A in FIG. 2. For example, FIG. 6 is an enlarged plan view showing an arrangement relationship between light-emitting elements and lenses arranged in a pixel area of an optical area. In FIG. 6, the outline indicated by the reference numeral OLED can represent the light-emitting area EA of the light-emitting element OLED. FIG. 7 is an enlarged view showing area A in FIG. 2. For example, FIG. 7 is an enlarged plan view showing an arrangement relationship among light-emitting elements, lenses, and cathode electrodes arranged in a pixel area of an optical area. FIG. 8 is a cross-sectional view taken along line I-I′ in FIG. 7. For example, FIG. 8 is a cross-sectional view taken along line I-I′ in FIG. 7 showing an arrangement relationship among light-emitting elements, lenses, and cathode electrodes.

The pixel area of the optical area CA can include a substrate PI, a circuit layer 12 on the substrate PI, a light-emitting element layer 14 on the circuit layer 12, an encapsulation layer 16 on the light-emitting element layer 14, a touch sensor layer 18 on the encapsulation layer 16, and the like. Since the substrate PI, the circuit layer 12, the light-emitting element layer 14, the encapsulation layer 16, the touch sensor layer 18, and the like arranged in the pixel area of the optical area CA are substantially the same in structural arrangement as the pixel area of the display area DA described in FIG. 4, the same reference numerals are assigned thereto, and the same description thereof can be omitted or provided in a simplified manner.

Referring to FIGS. 6 to 8, the display panel 100 can include: the organic compound layer EL arranged on the bank BNK; the cathode electrode CAT and the pattern layer PL arranged on the organic compound layer EL; a first inorganic insulating layer PAS1 arranged on the cathode electrode CAT and the pattern layer PL; the organic insulating layer PCL arranged on the first inorganic insulating layer PAS1; the second inorganic insulating layer PAS2 arranged on the organic insulating layer PCL; the touch sensor layer 18 arranged on the second inorganic insulating layer PAS2; and the lens LS arranged on the touch sensor layer 18. Here, the touch sensor layer 18 can include: the third buffer layer BUF3 configured to cover the second inorganic insulating layer PAS2; the bridge metal BRM arranged on the third buffer layer BUF3; the touch interlayer insulating layer TILD, made of an inorganic material and configured to cover the bridge metal BRM; the touch sensor metal TSM arranged on the bridge metal BRM; and the organic insulating layer PAC configured to cover the touch interlayer insulating layer TILD and the touch sensor metal TSM. The lens LS can be arranged below the touch interlayer insulating layer TILD so as to overlap the pattern layer PL. For example, a center of the lens LS can be arranged to overlap the pattern layer PL. Accordingly, a laser focused through the lens LS can be emitted onto the organic compound layer EL. For example, the optical area CA can include the lens LS arranged to emit a laser onto the organic compound layer EL.

The lens LS can be arranged below the touch interlayer insulating layer TILD, and can be formed in a shape convex toward the organic compound layer EL and/or the pattern layer PL. For example, the lens LS can include a flat upper surface and a predetermined curved surface LSa for focusing light, wherein the flat surface can be in contact with the touch interlayer insulating layer TILD, and the curved surface can be arranged to face the organic compound layer EL and/or the pattern layer PL. In this case, the shape of the lens LS can be represented by an aspect ratio. The aspect ratio of the lens LS, which is the ratio of a height H to a radius R, can be formed within a range of 0.1 to 1.0. Specifically, the aspect ratio of the lens LS can be formed within a range of 0.3 to 0.6. Accordingly, the height H of the lens LS can be 0.3 to 0.6 times the radius R.

In addition, the lens LS can be formed to have a predetermined refractive index. In addition, the lens LS can have a greater refractive index than the third buffer layer BUF3. For example, the refractive index of the lens LS can be 1.8 to 2.2, and the refractive index of the third buffer layer BUF3 can be 1.6 to 1.8. In this case, the lens LS and the third buffer layer BUF3 can be formed to have a refractive index difference of 0.1 or greater for focusing light by the lens LS.

The lens LS can be formed of a polymer-based organic material. In addition, the lens LS can be formed of a silicon-based inorganic material.

Since the lens LS includes the predetermined curved surface LSa for focusing light, a focal point of the lens LS can be positioned on one of the components constituting the organic compound layer EL. For example, a focal point of the lens LS can be positioned on the hole transport layer HTL of the organic compound layer EL. Here, the organic compound layer EL can include the hole injection layer HIL, the hole transport layer HTL, the emission layer EML, the electron transport layer ETL, and the electron injection layer EIL. In addition, the organic compound layer EL can further include an electron blocking layer EBL and a hole blocking layer HBL. In this case, the hole transport layer HTL, which facilitates the transport of a hole, can be formed by doping a p-dopant into a material constituting the hole transport layer HTL. In addition, the p-dopant can be composed of F4-TCNQ (2,3,5,6-tetrafluoro-7,7,8,8-tetracyano-quinidimethane), but is not limited thereto.

Accordingly, the display device according to an embodiment of the present disclosure can remove (or modify) the p-dopant in the hole transport layer HTL by using a laser irradiation process through the lens LS that overlaps the pattern layer PL, thereby preventing lateral leakage current from using the hole transport layer HTL as a path to flow into an adjacent light-emitting element OLED. For example, a laser focused through the lens LS can pass through the pattern layer PL. In addition, the laser that has passed through the pattern layer PL can be emitted onto the p-dopant in the hole transport layer HTL so as to remove or modify the p-dopant. Accordingly, the movement of the lateral leakage current flowing along the hole transport layer HTL is stopped by the p-dopants removed (or modified) by the laser. For example, the p-dopant removed (or modified) by the laser can serve as a barrier to block the flow of the lateral leakage current.

Referring to FIGS. 6 and 7, the lens LS can be arranged along a periphery of the light-emitting element OLED. For example, the lens LS can be arranged along the periphery of the light-emitting area EA, corresponding to the shape of the light-emitting area EA implemented by the light-emitting element OLED.

In addition, the lens LS can include an opening OP that is partially open. For example, if the light-emitting element OLED has a rectangular shape, the lens LS can be arranged along each surface of the light-emitting element OLED, and the opening OP can be formed to horizontally penetrate any one of the four surfaces of the lens LS.

The lens LS can be arranged along the periphery of the light-emitting element OLED, and the laser can be emitted along the lens LS so as to remove (or modify) the p-dopant in the hole transport layer HTL. Accordingly, the lateral leakage current moving through the hole transport layer HTL can be prevented from flowing into an adjacent light-emitting element OLED.

The lens LS can be arranged in a closed-loop shape along the periphery of the light-emitting element OLED, but is not necessarily limited thereto. For example, since the cathode electrode CAT can be damaged by the laser emitted through the lens LS, the lens LS can include the opening OP that overlaps the cathode electrode CAT.

Power can be applied to the organic compound layer EL of the light-emitting element OLED through a connection portion CATc of the cathode electrode CAT that overlaps the opening OP.

The cathode electrode CAT can include: a first area CATa configured to overlap the organic compound layer EL of the light-emitting element OLED that implements the light-emitting area EA; a second area CATb arranged to be spaced apart from the first area CATa on the plane; and the connection portion CATc configured to connect the first area CATa and the second area CATb. Here, the connection portion CATc configured to connect the first area CATa and the second area CATb can overlap the lens LS, and can be a third area of the cathode electrode CAT. In addition, the first area CATa can represent a portion of the cathode electrode CAT arranged inside the lens LS. Here, the first area CATa can represent a portion of the cathode electrode CAT that overlaps the light-emitting area EA of the light-emitting element OLED. In addition, the second area CATb can represent a portion of the cathode electrode CAT arranged outside the lens LS. Here, relative to the lens LS, the inside can indicate a direction toward a center of the lens LS relative to the lens LS, and the outside can indicate a direction opposite to the inside. In addition, the first area CATa can be a first cathode area; the second area CATb can be a second cathode area; and the connection portion CATc can be a third cathode area.

Since the possibility that the cathode electrode CAT is used as a path through which lateral leakage current flows may not be completely excluded, the display device according to embodiments of the present disclosure can structurally increases the length of the second path by positioning the connection portion CATc of each of the light-emitting elements OLED, which are arranged adjacent (or in close proximity) to each other, farther apart. Accordingly, the generation of light caused by lateral leakage current through the second path can be prevented or minimized.

Since the connection portion CATc of the cathode electrode CAT overlaps the opening OP of the lens LS, a path through which lateral leakage current flows can be structurally predicted based on the position of the opening OP. Accordingly, the second path will be described below based on the position of the opening OP, which is configured to prevent or minimize the generation of light caused by lateral leakage current.

Since the opening OP can be arranged to overlap the connection portion CATc of the cathode electrode CAT, the length of the second path can be increased by positioning the openings OP of the lenses LS, which are arranged adjacent (or in close proximity) to each other, farther apart.

Referring to FIGS. 6 and 7, the lenses LS arranged adjacent to each other can be arranged to be spaced a first distance D1, which is the shortest distance, apart from each other. In addition, the openings OP of the respective lenses LS arranged adjacent to each other can be arranged to be spaced a second distance D2 apart from each other. Accordingly, the display panel 100 can increase the length of the second path by positioning the openings OP of the respective lenses LS farther apart than the first distance D1.

Accordingly, since the connection portions CATc, which overlaps the openings OP of the respective lenses LS arranged adjacent to each other, are arranged to be spaced a second distance D2, which is greater than the first distance D1, apart from each other, the path through which the lateral leakage current flows by means of the cathode electrode CAT can be formed to have a structurally increased length.

For example, a path can be formed to allow the lateral leakage current to flow between the first areas CATa of the cathode electrode CAT arranged within the lenses LS arranged adjacent to each other. In this case, the path formed to allow the lateral leakage current to flow between the first areas CATa of the cathode electrode CAT, which are adjacent to each other, can be the second path. For example, in the light-emitting elements OLED arranged adjacent to each other, two connection portions CATc arranged between two first areas CATa and a portion of the second area CATb connecting the two connection portions CATc can be provided as the second path.

Referring to FIGS. 6 and 7, the second path will be described below based on an example of two lens arranged adjacent to each other, which are a first lens LS1 and a second lens LS2.

The first lens LS1 and the second lens LS2, which are arranged adjacent to each other, can be arranged to have the predetermined first distance D1 therebetween. In this case, the first lens LS1 can include a first opening OP1; the second lens LS2 can include a second opening OP2; and the first opening OP1 and the second opening OP2 can be arranged to have a second distance D2, which is greater than the first distance D1, therebetween. For example, by not arranging the openings OP on a first surface of the first lens LS1 and a second surface of the second lens LS2, which are arranged to face each other, the second distance D2 can be formed greater than the first distance D1. For example, by not arranging the first opening OP1 and the second opening OP2 on the surfaces of the first lens LS1 and the second lens LS2 facing each other, the second distance D2 can be formed greater than the first distance D1. For example, by arranging only one opening OP on a virtual line L connecting a center C1 of the first lens LS1 and a center C2 of the second lens LS2, the second distance D2 can be formed greater than the first distance D1. For example, even when the first opening OP1 and the second opening OP2 are arranged on the virtual line L, only one of the first opening OP1 and the second opening OP2 can be arranged on the surfaces of the first lens LS1 and the second lens LS2 facing each other. Accordingly, the second distance D2 can be formed greater than the first distance D1.

In addition, the organic compound layer EL constituting a first light-emitting element OLED1 and the first area CATa of the cathode electrode CAT can be arranged within the first lens LS1 on the plane. In addition, the organic compound layer EL constituting a second light-emitting element OLED2 and the first area CATa of the cathode electrode CAT can be arranged within the second lens LS2 on the plane. In addition, a first connection portion CATc1 of the cathode electrode CAT can be arranged to overlap the first opening OP1. In addition, a second connection portion CATc2 of the cathode electrode CAT can be arranged to overlap the second opening OP2.

Since the second distance D2 is formed to be greater than the first distance D1, and the second path connecting the first connection portion CATc1 and the second connection portion CATc2 is formed to take a detour along peripheries of the first lens LS1 and the second lens LS2, the generation of light caused by lateral leakage current moving along the second path can be prevented or minimized. For example, the second area CATb connecting the first connection portion CATc1 and the second connection portion CATc2 can be formed to take a detour along the peripheries of the first lens LS1 and the second lens LS2. As illustrated in FIG. 7, the second area CATb connecting the first connection portion CATc1 and the second connection portion CATc2 can be formed outside the first lens LS1 and the second lens LS2. Accordingly, the generation of light caused by lateral leakage current moving along the second path can be prevented or minimized.

A display device according to one or more embodiments of the present disclosure can be described as follows:

A display device according to one or more embodiments of the present disclosure can include: a display panel including a display area and an optical area, and a sensor arranged to correspond to the optical area. The display panel can include: a substrate; a circuit layer arranged on the substrate; an anode electrode arranged on the circuit layer; an organic compound layer arranged on the anode electrode and including a light-emitting area; a cathode electrode and a pattern layer arranged on the organic compound layer; an encapsulation layer arranged on the cathode electrode and the pattern layer; a touch sensor layer arranged on the encapsulation layer; and a plurality of lenses configured to overlap the pattern layer.

According to one or more embodiments of the present disclosure, the lens can be arranged on the touch sensor layer to be spaced apart from the pattern layer.

According to one or more embodiments of the present disclosure, the touch sensor layer can include: a touch buffer layer arranged on the encapsulation layer; a bridge metal arranged on the touch buffer layer; a touch interlayer insulating layer made of an inorganic material and configured to cover the bridge metal; and a touch sensor metal arranged on the bridge metal, wherein the lens can be arranged below the touch interlayer insulating layer.

According to one or more embodiments of the present disclosure, a refractive index of the lens can be greater than a refractive index of the touch buffer layer.

According to one or more embodiments of the present disclosure, the lens can be formed to be convex toward the pattern layer.

According to one or more embodiments of the present disclosure, a focal point of the lens can be positioned in a hole transport layer of the organic compound layer.

According to one or more embodiments of the present disclosure, the hole transport layer can include a p-dopant.

According to one or more embodiments of the present disclosure, the display panel can further include a bank arranged on a planarization layer of the circuit layer, wherein a portion of the pattern layer can be arranged on the bank to overlap the lens.

According to one or more embodiments of the present disclosure, the lens can be arranged along a periphery of the light-emitting area.

According to one or more embodiments of the present disclosure, the lens can include an opening, which is partially open.

According to one or more embodiments of the present disclosure, the cathode electrode can include: a first area arranged inside the lens to overlap the light-emitting area; a second area arranged outside the lens; and a connection portion configured to connect the first area and the second area, wherein the connection portion can overlap the opening.

According to one or more embodiments of the present disclosure, two of the plurality of lenses arranged adjacent to each other can be arranged to have a first distance therebetween; the openings of the two lenses can be arranged to have a second distance therebetween; and the second distance can be greater than the first distance.

According to one or more embodiments of the present disclosure, the first distance can be the shortest distance between the two lenses.

According to one or more embodiments of the present disclosure, the plurality of lenses can include a first lens and a second lens arranged adjacent to each other, and the opening can be not arranged on each of surfaces of the first lens and the second lens arranged to face each other.

According to one or more embodiments of the present disclosure, the plurality of lenses can include a first lens and a second lens arranged adjacent to each other, and only one opening can be arranged on a virtual line configured to connect a center of the first lens and a center of the second lens.

According to one or more embodiments of the present disclosure, the plurality of lenses can include a first lens and a second lens arranged adjacent to each other; the first lens can include a first opening; and the second lens can include a second opening; and only one of the first opening and the second opening can be arranged on surfaces of the first and second lenses configured to face each other.

According to one or more embodiments of the present disclosure, the optical area can include: a plurality of pixel areas in which pixels are arranged; and a light-transmitting area arranged between the plurality of pixel areas, and the pattern layer arranged in the pixel areas can extend into the light-transmitting area.

A display panel according to one or more embodiments of the present disclosure can include a display area and an optical area. The display panel can comprise: a substrate; a circuit layer arranged on the substrate; an anode electrode arranged on the circuit layer; an organic compound layer arranged on the anode electrode and including a light-emitting area; a cathode electrode and a pattern layer arranged on the organic compound layer; an encapsulation layer arranged on the cathode electrode and the pattern layer; a touch sensor layer arranged on the encapsulation layer; and a plurality of lenses configured to overlap the pattern layer.

According to one or more embodiments of the present disclosure, the lens can be arranged on the touch sensor layer to be spaced apart from the pattern layer.

According to one or more embodiments of the present disclosure, the display panel can further comprise: a bank arranged on a planarization layer of the circuit layer, wherein a portion of the pattern layer is arranged on the bank to overlap the lens.

According to one or more embodiments of the present disclosure, the lens can be arranged along a periphery of the light-emitting area.

According to one or more embodiments of the present disclosure, the optical area can comprise: a plurality of pixel areas in which pixels are arranged; and a light-transmitting area arranged between the plurality of pixel areas; and the pattern layer arranged in the pixel areas extends into the light-transmitting area.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and can be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

### LIST OF REFERENCE NUMBERS

100: Display panel 200: Optical device
AND: Anode electrode BNK: Bank
CAT: Cathode electrode EL: Organic compound layer
LS: lens PL: Pattern layer

What is claimed is:

1. A display device comprising:
a display panel including a display area and an optical area; and
a sensor arranged to correspond to the optical area,
wherein the display panel comprises:
a substrate;
a circuit layer arranged on the substrate;
an anode electrode arranged on the circuit layer;
an organic compound layer arranged on the anode electrode and including a light-emitting area;
a cathode electrode and a pattern layer arranged on the organic compound layer;
an encapsulation layer arranged on the cathode electrode and the pattern layer;
a touch sensor layer arranged on the encapsulation layer; and
a plurality of lenses configured to overlap the pattern layer.

2. The display device of claim 1, wherein a lens among the plurality of lenses is arranged on the touch sensor layer to be spaced apart from the pattern layer.

3. The display device of claim 2, wherein the touch sensor layer comprises:
a touch buffer layer arranged on the encapsulation layer;
a bridge metal arranged on the touch buffer layer;
a touch interlayer insulating layer including an inorganic material and configured to cover the bridge metal; and
a touch sensor metal arranged on the bridge metal, and
wherein the lens is arranged below the touch interlayer insulating layer.

4. The display device of claim 3, wherein a refractive index of the lens is greater than a refractive index of the touch buffer layer.

5. The display device of claim 2, wherein the lens is convex toward the pattern layer.

6. The display device of claim 5, wherein a focal point of the lens is positioned in a hole transport layer of the organic compound layer.

7. The display device of claim 6, wherein the hole transport layer comprises a p-dopant.

8. The display device of claim 1, further comprising:
a bank arranged on a planarization layer of the circuit layer,
wherein a portion of the pattern layer is arranged on the bank to overlap at least one of the plurality of lenses.

9. The display device of claim 1, wherein a lens among the plurality of lenses is arranged along a periphery of the light-emitting area.

10. The display device of claim 9, wherein the lens comprises an opening, which is partially open.

11. The display device of claim 10, wherein the cathode electrode comprises:
a first area arranged inside the lens to overlap the light-emitting area;
a second area arranged outside the lens; and
a connection portion configured to connect the first area and the second area, and
wherein the connection portion overlaps the opening of the lens.

12. The display device of claim 11, wherein:
two lenses among the plurality of lenses that are arranged be adjacent to each other are arranged to have a first distance therebetween,
openings of the two lenses are arranged to have a second distance therebetween, and
the second distance is greater than the first distance.

13. The display device of claim 12, wherein the first distance is the shortest distance between the two lenses.

14. The display device of claim 11, wherein:
the plurality of lenses comprise a first lens and a second lens arranged adjacent to each other, and
an opening is not arranged on each of surfaces of the first lens and the second lens arranged to face each other.

15. The display device of claim 11, wherein:
the plurality of lenses comprise a first lens and a second lens arranged adjacent to each other, and
only one opening is arranged on a virtual line configured to connect a center of the first lens and a center of the second lens.

16. The display device of claim 11, wherein:
the plurality of lenses comprise a first lens and a second lens arranged adjacent to each other,
the first lens comprises a first opening and the second lens comprises a second opening, and
only one of the first opening and the second opening is arranged on surfaces of the first and second lenses configured to face each other.

17. The display device of claim 1, wherein the optical area comprises:
a plurality of pixel areas in which pixels are arranged; and
a light-transmitting area arranged between the plurality of pixel areas, and
wherein the pattern layer arranged in the plurality of pixel areas extends into the light-transmitting area.

18. A display panel, comprising:
a substrate;
a circuit layer arranged on the substrate;
an anode electrode arranged on the circuit layer;
an organic compound layer arranged on the anode electrode and including a light-emitting area;
a cathode electrode and a pattern layer arranged on the organic compound layer;
an encapsulation layer arranged on the cathode electrode and the pattern layer;
a touch sensor layer arranged on the encapsulation layer; and
a plurality of lenses configured to overlap the pattern layer.

19. The display panel of claim 18, wherein at least one of the plurality of lenses is arranged on the touch sensor layer to be spaced apart from the pattern layer.

20. The display panel of claim 18, wherein an the optical area of the display panel comprises:
a plurality of pixel areas in which pixels are arranged; and
a light-transmitting area arranged between the plurality of pixel areas, and
wherein the pattern layer arranged in the plurality of pixel areas extends into the light-transmitting area.
